(19) United States
(12) Patent Application Publication
(10) Pub. No.: US 2013/0043589 A1
(43) Pub. Date: Feb. 21, 2013

(54) Methods of Forming a Non-Planar Cap Layer Above Conductive Lines on a Semiconductor Device

(71) Applicants: Ryoung-Han Kim, Clifton Park, NY (US); Errol Todd Ryan, Clifton Park, NY (US)

(72) Inventors: Ryoung-Han Kim, Clifton Park, NY (US); Errol Todd Ryan, Clifton Park, NY (US)

(73) Assignee: GLOBALFOUNDRIES INC., Grand Cayman (KY)

(21) Appl. No.: 13/210,858

(22) Filed: Aug. 16, 2011

(51) Int. Cl. H01L 23/532; H01L 21/768; H01L 23/50

(52) U.S. Cl. 257/741; 257/786; 438/672; 257/E23.161; 257/E21.585

(57) ABSTRACT

Disclosed herein are various methods of forming methods of forming a non-planar cap layer above a conductive line on a semiconductor device, and to devices incorporating such a non-planar cap layer. In one illustrative example, the method includes forming a conductive structure in a layer of insulating material, recessing an upper surface of the conductive structure relative to an upper surface of the layer of insulating material such that the recessed upper surface of the conductive structure and the upper surface of the layer of insulating material are positioned in different planes and, after recessing the upper surface of the conductive structure, forming a first cap layer on the conductive structure and the layer of insulating material. In another example, the device includes a conductive structure positioned in a layer of insulating material and a first cap layer formed on the layer of insulating material and the conductive structure, wherein a first interface between the first cap layer and the layer of insulating material is located in a first plane and a second interface between the first cap layer and the conductive structure is located in a second plane that is different from the first plane.

### BACKGROUND OF THE INVENTION

1. Field of the Invention

Generally, the present disclosure generally relates to the manufacturing of sophisticated semiconductor devices, and, more specifically, to various methods of forming a non-planar cap layer above conductive lines on a semiconductor device, and to devices incorporating such a non-planar cap layer.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NMOS and PMOS transistors) represent one important type of circuit elements that substantially determine the performance of the integrated circuits. A field effect transistor, irrespective of whether an NMOS transistor or a PMOS transistor is considered, typically comprises so-called PN junctions that are formed by an interface of highly doped regions, referred to as drain and source regions, with a slightly doped or non-doped region, such as a channel region, disposed between the highly doped regions source/drain regions. Additionally, a typical integrated circuit device is comprised of a plurality of conductive interconnections, such as conductive lines and conductive contacts or vias, positioned in multiple layers of insulating material formed above the transistors—so-called metallization layers. These metallization layers allow electrical signals to propagate between the transistors formed above the substrate.

The performance of a field effect transistor depends upon a variety of factors, such as the conductivity of the channel region, the dopant concentration of various doped regions, the mobility of the charge carriers and, for a given extension of the channel region in the transistor width direction, on the distance between the source and drain regions, which is also referred to as the channel length of the transistor. In recent years, integrated circuit manufacturers have made great progress in increasing the performance of transistors by, among other things, greatly reducing or scaling the channel length of the transistors. Efforts have also been made to improve the basic structures and materials used in the metallization layers to reduce the signal delay associated with crosstalk between adjacent lines in one or more of the metallization layers. Such techniques include the use of more conductive metals for the conductive structures, such as copper, and the use of so-called low-k insulating materials (k value less than 3).

FIGS. 1A-1C depict one illustrative process flow used to form a conductive line in a semiconductor device 100. In general, the integrated circuit device 100 includes a plurality of schematically depicted conductive structures 10, e.g., conductive lines, formed in a layer of insulating material 12 that is positioned above a semiconducting substrate (not shown). An enlarged view of the conductive structure 10 is depicted in FIG. 1C. The conductive structures 10 may be of any desired configuration and material, such as copper or aluminum, and they may be formed using a variety of known techniques. In one example, the conductive structures 10 are made of copper and the layer of insulating material is a low-k insulating material. In one illustrative technique, a plurality of openings are formed in the layer of insulating material 12 by performing one or more etching process through a patterned mask layer (not shown). Thereafter, the conductive materials that will become part of the conductive structure 10 are deposited in the opening in the layer of insulating material 12 and above the surface of the layer of insulating material 12. Then, a chemical mechanical polishing (CMP) process is performed to remove the excess amount of conductive materials positioned outside of the openings in the layer of insulating material 12. After the CMP process is performed, the upper surface 10S of the conductive structures 10 is approximately planar with the upper surface 12S of the layer of insulating material 12. Additionally, at this point the device 100 may be subjected to a cleaning process, such as a plasma cleaning process, to remove any residual metal oxides, such as copper oxides, that might have formed on the upper surface 10S of the conductive structures 10 during or after the CMP process.

Next, as shown in FIG. 1B, a cap layer 14 is deposited on the device 100 to effectively seal and protect the underlying conductive structures 10 and insulating layer 12, and to facilitate the performance of subsequent processing operations on the device 100. The cap layer 14 may be of any desired material, such as a carbon-doped silicon nitride, it may be formed to any desired thickness, e.g., 10-20 nm, and it may be formed by performing a variety of known techniques, a chemical vapor deposition (CVD) process. Unfortunately, especially when the layer of insulating material 12 is made of a low-k material, the deposition of the cap layer 14 tends to damage the layer of insulating material 12, as schematically depicted by the damaged regions 16. The extent and type of damage in the region 16 depends upon, among other things, the particular process parameters of the deposition process used to form the cap layer 14 and the material used for the layer of insulating material 12. In general, the type of damage caused in the region 16 can be generally categorized as surface type defects and carbon depletion and subsequent silanol formation or dangling bonds. The depth of the region 16 may also vary depending upon the particular application, e.g., the depth of the damaged region 16 may be approximately 10 or so nm.

As noted earlier, FIG. 1C is an enlarged view of the conductive structure 10. In this view, an illustrative barrier layer 11, made form a material such as tantalum or tantalum nitride, is depicted as being positioned between the bulk of the conductive structure 10 and the layer of insulating material 12. In some cases, the barrier layer 11 may have a thickness of approximately 3-6 nm. The barrier layer 11 was not depicted in FIGS. 1A-1B so as not to obscure the present discussion. One purpose of the barrier layer 11 is to prevent the migration of the material of the conductive structure 10 into the layer of insulating material 12, e.g., to prevent the migration of copper into the layer of insulating material 12.

Unfortunately, since the interface 18 between the conductive structure 10 and the cap layer 14 and the interface 20 between the layer of insulating material 12 and the cap layer 14 are on the same plane, the distance that such migrating metal material must travel before material enter into the layer of insulating material 12 is very short, as indicated by the arrows 22. Additionally, the presence of the damaged regions 16 in the layer of insulating material 12 tends to make such migration easier because the defects in the damage region facilitate the diffusion of ions and electrons. Such undesirable migration of the metal or conductive materials may, at best, be merely detrimental to the overall performance of the device, e.g., such migration may result in increased crosstalk as the effective dielectric constant of the regions of the insulating material 12 where such migrated metals are present, effectively increases the “conductivity” of the layer of insulating material. In a worst case scenario, if the amount of metal migration is sufficient, a high leakage current or an electrical short may be established between adjacent conductive structures 10 which may lead to total device failure.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is generally directed to various methods of forming a non-planar cap layer above conductive lines on a semiconductor device, and to devices incorporating such a non-planar cap layer. In one illustrative example, the method includes forming a conductive structure in a layer of insulating material, recessing an upper surface of the conductive structure relative to an upper surface of the layer of insulating material such that the recessed upper surface of the conductive structure and the upper surface of the layer of insulating material are positioned in different planes and, after recessing the upper surface of the conductive structure, forming a first cap layer on the conductive structure and the layer of insulating material.

In another example, the present disclosure is directed to a device that includes a conductive structure positioned in a layer of insulating material and a first cap layer formed on the layer of insulating material and the conductive structure, wherein a first interface between the first cap layer and the layer of insulating material is located in a first plane and a second interface between the first cap layer and the conductive structure is located in a second plane that is different from the first plane.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depict one illustrative prior art process flow for forming conductive structures in a layer of insulating material; and

FIGS. 2A-2E depict one various illustrative examples of using the methods disclosed herein to form a non-planar cap layer above a conductive structure on a semiconductor device, and to devices incorporating such a non-planar cap layer.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

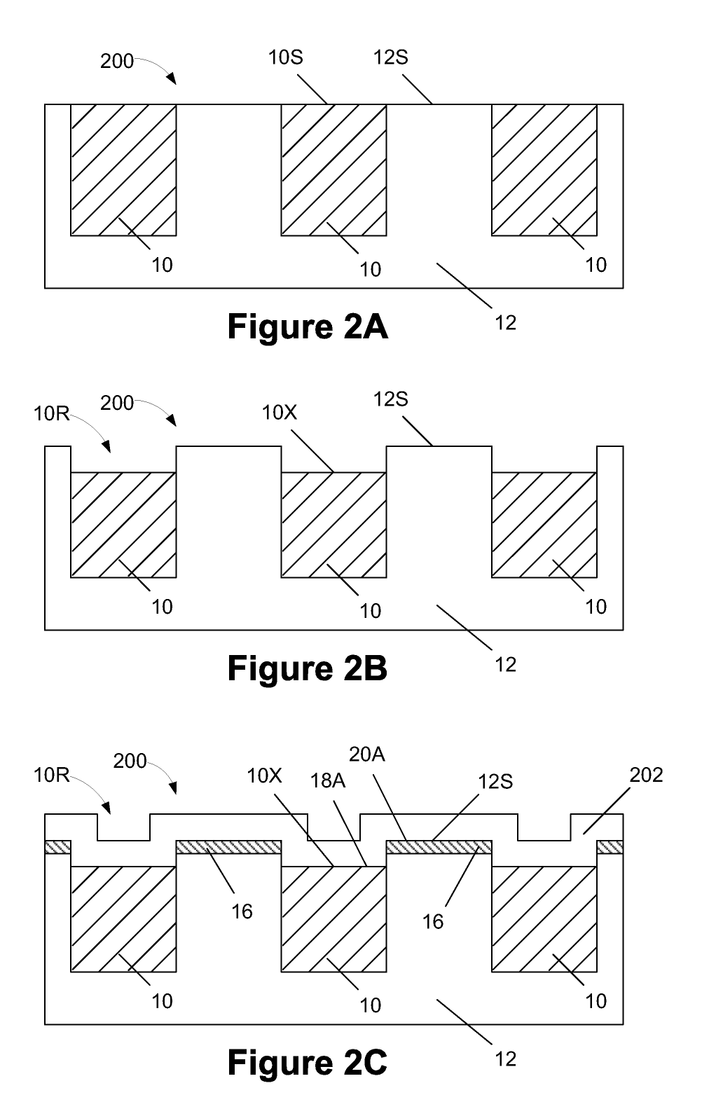

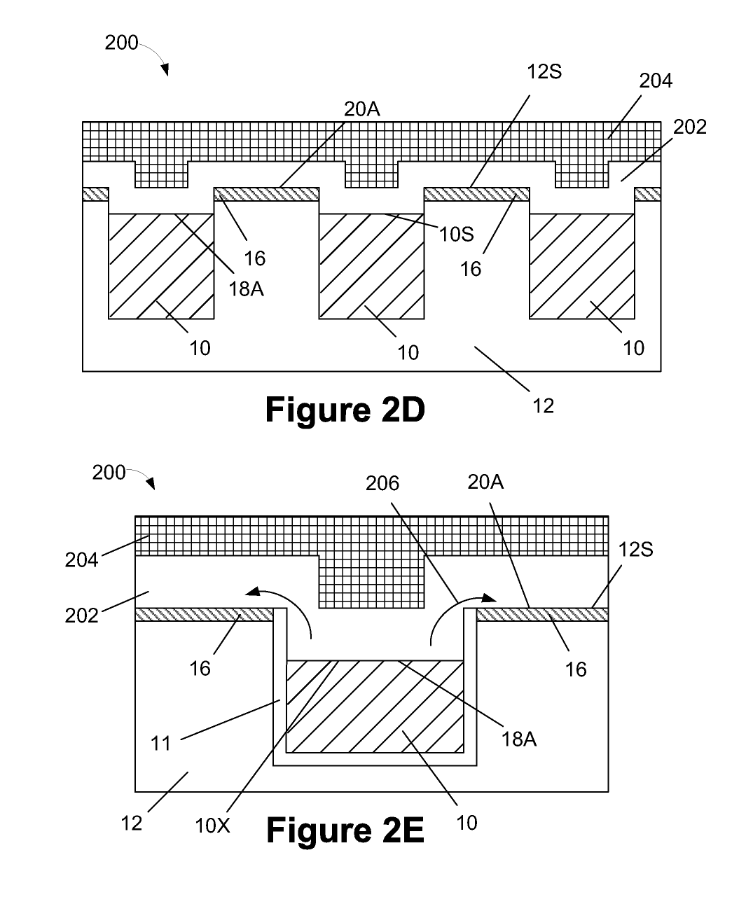

The present disclosure is directed to various methods of forming a non-planar cap layer about conductive lines on a semiconductor device, and to devices incorporating such a non-planar cap layer. As will be readily apparent to those skilled in the art upon a complete reading of the present application, the present method is applicable to a variety of technologies, e.g., NMOS, PMOS, CMOS, etc., and is readily applicable to a variety of devices, including, but not limited to, logic devices, memory devices, etc. With reference to FIGS. 2A-2E, various illustrative embodiments of the methods disclosed herein will now be described in more detail.

FIG. 2A is a simplified view of an illustrative integrated circuit device 200 at an early stage of manufacturing that is formed above a semiconducting substrate (not shown). The substrate may have a variety of configurations, such as the depicted bulk silicon configuration. The substrate may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate may also be made of materials other than silicon.

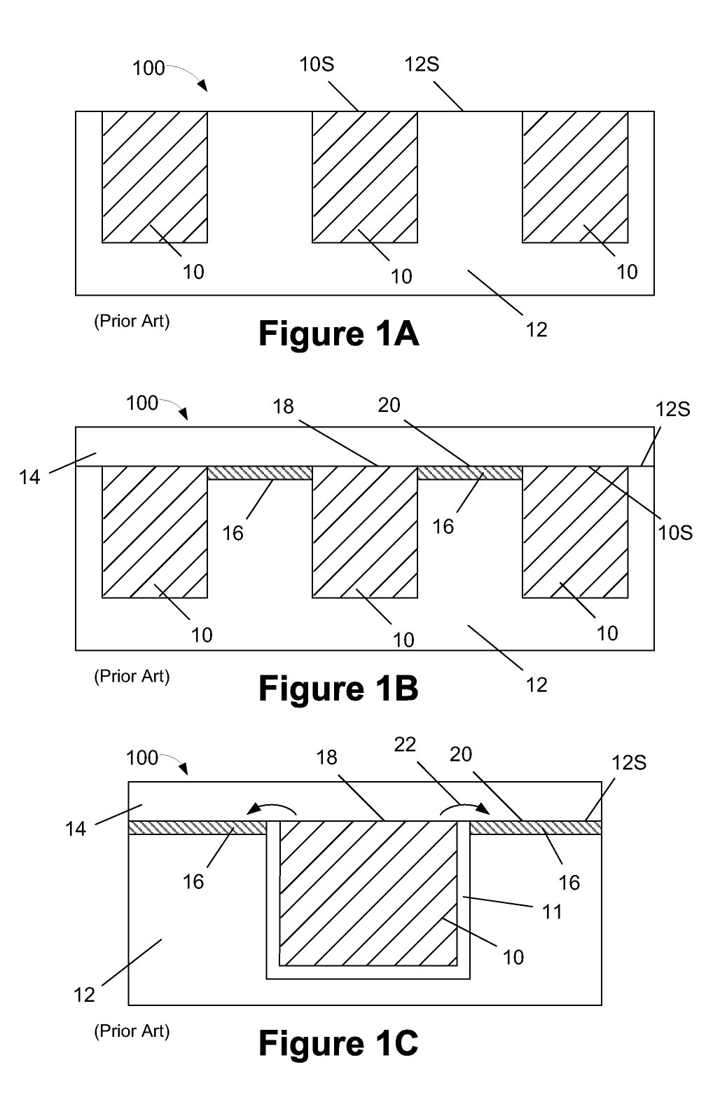

In general, in FIG. 2A, the device 200 is depicted at the point of fabrication that corresponds to that depicted in FIG. 1A for the device 100. Thus, the discussion about illustrative materials and methods of manufacture employed in making the device 100 apply equally to the device 200 up to this point of fabrication. Of course, to the extent that like reference numbers for various components are used, the previous discussion of those components in connection with the device 100 apply equally as well to the device 200. At the point depicted in FIG. 2A, a CMP process has been performed on the device 200 such that the surface 10S of the conductive structure 10 is approximately planar with the surface 12S of the layer of insulating material 12.

The conductive structures 10 are schematically depicted and are intended to be representative of a variety of different structures that may be employed in manufacturing an integrated circuit device. For example, the conductive structure 10 may be a conductive metal line or via formed in a metallization layer of an integrated circuit device. The conductive structures 10 may be made of a variety of different metals, e.g., copper, aluminum, tungsten, etc., it may have any desired size and configuration, and it may be manufactured using a variety of known processing techniques. For example, the conductive structure 10 may be a conductive line in a metallization layer of an integrated circuit device and it may be formed by performing known damascene techniques. Similarly, the layer of insulating material 12 may be comprised of any desired insulating material, such a low-k insulating material (k value less than 4). The layer of insulating material 12 may be formed by performing any of a variety of known deposition processes, such as a CVD process.

Next, as shown in FIG. 2B, one or more process operations are performed to form a recess 10R above the conductive structures 10. More specifically, after this is performed, the recessed upper surface 10X of the conductive structure 10 is positioned in a different horizontal plane than the upper surface 12S of the layer of insulating material 12. That is, the recessed upper surface 10X is recessed relative to the upper surface 12S of the layer of insulating material 12. The magnitude or depth of the recess 10R may vary depending upon the particular application. In general, the depth of the recess 10R should be of sufficient depth to prevent or at least inhibit the migration of undesirable metals into the layer of insulating material 12. In one illustrative example, the depth of the recess 10R may range from approximately 2-10 nm. The recesses 10R may be formed by a variety of techniques. In one example, the a portion of the conductive structure 10 may be subjected to a controlled oxidation process, and the oxide material may be subsequently removed by performing one or more wet or dry etching processes. In one particularly illustrative example where the conductive structure is comprised of copper, SC1 may be used to oxidize the desired amount of the conductive structure 10 to be removed, and a wet etching process may be performed using, for example, citric acid to remove the copper oxide material. In another illustrative example, a wet or dry etching process may be performed on the conductive structure 10 to form the recesses 10R. After the recesses 10R are formed, a cleaning process, such as a plasma based cleaning process may be performed on the device 200 in an effort to insure that any undesirable material, such as oxides formed on the conductive structures 10 are removed.

Next, as shown in FIG. 2C, a non-planar first cap layer 202 is formed on the device 200. More specifically, in the depicted example, the first cap layer 202 is formed on the exposed surfaces 10X, 12S of the conductive structure 10 and the layer of insulating material 12, respectively. The first cap layer 202 is non-planar in the sense that at least its bottom surface is non-planar as it conforms to the recesses 10R and the upper surface 12S of the layer of insulating material 12. As with the deposition of the cap layer 14 as discussed in the background section of this application, the deposition of the first cap layer 202 also results in a damages region 16 in the layer of insulating material 12. However, using the methodologies disclosed herein, the interface 18A between the first cap layer 202 and the conductive structures 10 is below, or in a different horizontal plane, as compared to the interface 20A between the layer of insulating material 12 and the first cap layer 202. That is, comparing FIG. 2C of the present disclosure with FIG. 1B (the prior art), is can be readily seen that the recessed upper surface 10X of the device 200 is recessed relative to the upper surface 12S of the layer of insulating material 12, whereas, in the prior art device 100 than the upper surface 10S of the conductive structure 10 is positioned in the same plane as the upper surface 12S of the layer of insulating material 12. The first cap layer 202 may be comprised of any of a variety of different materials, e.g., silicon nitride, carbon doped silicon nitride, silicon carbide, etc., and it thickness may vary depending on the particular application, e.g., in some cases it may have a thickness ranging from approximately 1-10 nm. The first cap layer 202 may be formed by performing a conformal deposition process, e.g., an atomic layer deposition (ALD) process, a modified CVD process, etc.

Next, as shown in FIG. 2D, a second cap layer 204 is formed above the non-planar first cap layer 202. The second cap layer 204 may be comprised of any of a variety of different materials, e.g., silicon nitride, carbon doped silicon nitride, etc., and its thickness may vary depending on the particular application, e.g., in some cases it may have a thickness ranging from approximately 10-20 nm. The second cap layer 204 may be formed by performing deposition process, such as a CVD process.

FIG. 2E is an enlarged view of a conductive structure 10 of the device 200. In this view, an illustrative barrier layer 11, made form a material such as tantalum or tantalum nitride, is depicted as being positioned between the bulk of the conductive structure 10 and the layer of insulating material 12. The barrier layer 11 was not depicted in FIGS. 2A-2D so as not to obscure the present invention. Using the presently disclosed methods, the distance that a migrating metal material from the conductive structure 10 must travel before metal material enters into the layer of insulating material 12 is much greater, as indicated by the arrows 206, than the corresponding distance, as indicated by the arrows 22, for the prior art device 100 depicted in FIG. 1C. This greater distance is due to the fact that, in the device 200, the recesses 10R were formed and the interface 18A between the first cap layer 202 and the conductive structures 10 is below, or in a different horizontal plane, as compared to the interface 20A between the layer of insulating material 12 and the first cap layer 202. This increased distance makes it more difficult for metals to migrate from the conductive structure into the layer of insulating material 12.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A device, comprising:
a layer of insulating material;
a conductive structure positioned in said layer of insulating material; and
a first cap layer formed on said layer of insulating material and said conductive structure, wherein a first interface between said first cap layer and said layer of insulating material is located in a first plane and a second interface between said first cap layer and said conductive structure is located in a second plane that is different from said first plane.

2. The device of claim 1, wherein said first and second planes are separated by a distance of about 2 nm or more.

3. The device of claim 1, wherein said conductive structure is a conductive metal line.

4. The device of claim 3, wherein said conductive metal line is comprised of copper.

5. The device of claim 1, further comprising a second cap layer formed on said first cap layer.

6. The device of claim 1, wherein said layer of insulating material is comprised of a low-k insulating material.

7. The device of claim 5, wherein said first and second cap layers are comprised of the same material.

8. The device of claim 5, wherein said first and second cap layers are comprised of different materials.

9. The device of claim 1, wherein an upper surface of said conductive structure is recessed relative to an upper surface of said layer of insulating material.

10. A device, comprising:
a layer of low-k insulating material;
a conductive metal structure positioned in said layer of low-k insulating material, wherein an upper surface of said conductive metal structure is recessed relative to an upper surface of said layer of low-k insulating material;
a first cap layer formed on said layer of low-k insulating material and said conductive metal structure; and
a second cap layer formed on said first cap layer.

11. A device, comprising:
a layer of low-k insulating material;
a conductive metal line comprised of copper positioned in said layer of low-k insulating material, wherein an upper surface of said conductive metal line is recessed relative to an upper surface of said layer of low-k insulating material; and
a first cap layer formed on said layer of low-k insulating material and said conductive metal line.

12. The device of claim 11, further comprising a second cap layer formed on said first cap layer.

13. A method, comprising:
forming a conductive structure in a layer of insulating material;
recessing an upper surface of said conductive structure relative to an upper surface of said layer of insulating material such that said upper surface of said conductive structure and said upper surface of said layer of insulating material are positioned in different planes; and
after recessing said upper surface of said conductive structure, forming a first cap layer on said conductive structure and said layer of insulating material.

14. The method of claim 13, wherein recessing said upper surface of said conductive structure relative to said upper surface of said layer of insulating material comprises oxidizing a portion of said conductive structure and performing at least one etching process to remove the oxidized portions of said conductive structure.

15. The method of claim 13, wherein said layer of insulating material comprises a low-k insulating material.

16. The method of claim 13, wherein forming said conductive structure in said layer of insulating material comprised depositing a layer of a conductive material in an opening formed in said layer of material and performing a chemical mechanical planarization process to remove excess amounts of said layer of conductive material positioned outside of said opening in said layer of insulating material.

17. The method of claim 13, wherein said recessing said upper surface of said conductive structure relative to said upper surface of said layer of insulating material is performed such that said first and second planes are separated by a distance of at least 2 nm.

18. The method of claim 13, wherein forming said conductive structure comprises forming a conductive metal line comprised of copper.

19. The method of claim 13, wherein, prior to performing said recessing of said upper surface of said conductive structure relative to said upper surface of said layer of insulating material, performing a plasma cleaning process on said conductive structure and said layer of insulating material.

20. The method of claim 13, further comprising forming a second cap layer on said first cap layer.

21. The method of claim 13, wherein recessing said upper surface of said conductive structure relative to said upper surface of said layer of insulating material comprises performing a wet or dry etching process on said conductive structure to recess said upper surface of said conductive structure.

22. A method, comprising:
forming a conductive metal line in a layer of low-k insulating material;
recessing an upper surface of said conductive metal line such that said upper surface of said conductive metal line is recessed relative to an upper surface of said layer of low-k insulating material; and
after recessing said upper surface of said conductive metal line, forming a first cap layer on said conductive metal line and said layer of low-k insulating material.

23. The method of claim 22, wherein recessing said upper surface of said conductive metal line comprises oxidizing a portion of said conductive metal line and performing an etching process to remove the oxidized portions of said conductive metal line.

24. The method of claim 22, wherein recessing said upper surface of said conductive metal line is performed such that said recessed upper surface of said conductive metal line is position below said upper surface of said layer of low-k insulating material by a distance of about 2 nm or more.

25. The method of claim 22, wherein said conductive metal line is comprised of copper.

26. The method of claim 22, wherein, prior to performing said recessing of said upper surface of said conductive metal line, performing a plasma cleaning process on said conductive metal line and said layer of low-k insulating material.

27. The method of claim 22, further comprising forming a second cap layer on said first cap layer.

28. The method of claim 22, wherein recessing said upper surface of said conductive metal line comprises performing a wet or dry etching process on said conductive metal line to form said recessed upper surface of said conductive metal line.
